(19) United States
(12) Patent Application Publication
(10) Pub. No.: US 2024/0321836 A1
(43) Pub. Date: Sep. 26, 2024

(54) LIGHT SOURCE AND LIGHT-EMITTING MODULE

(71) Applicant: NICHIA CORPORATION, Anan-shi (JP)

(72) Inventor: Akira HORI, Tokushima-shi (JP)

(21) Appl. No.: 18/601,704

(22) Filed: Mar. 11, 2024

(30) Foreign Application Priority Data
Mar. 23, 2023 (JP) 2023-047346

(51) Int. Cl. H01L 25/075; H01L 33/50; H01L 33/54; H01L 33/58

(52) U.S. Cl. CPC H01L 25/0753; H01L 33/502; H01L 33/54; H01L 33/58

(57) ABSTRACT

A light source includes a plurality of light-emitting elements, a covering member, and a plurality of light-transmissive members. The covering member is disposed between adjacent ones of the plurality of light-emitting elements and on an outer periphery surrounding an entirety of the plurality of light-emitting elements with upper surfaces of the plurality of light-emitting elements being exposed from the covering member. The covering member collectively holds the plurality of light-emitting elements. The plurality of light-transmissive members include a plurality of first light-transmissive members disposed on respective ones of the plurality of light-emitting elements, and at least one second light-transmissive member disposed on the covering member located on the outer periphery, the at least one second light-transmissive member having a thickness smaller than a thickness of each of the plurality of first light-transmissive members.

### CROSS-REFERENCE TO RELATED APPLICATION

This application claims priority to Japanese Patent Application No. 2023-047346, filed on Mar. 23, 2023, the disclosure of which is hereby incorporated herein by reference in its entirety.

### BACKGROUND

The present disclosure relates to a light source and a light-emitting module.

In recent years, a light source in which a plurality of light-emitting elements are two-dimensionally arranged has been used in various fields, such as a display device, a lighting device, and a flash. For example, Japanese Patent No. 2013-16588A discloses a light source, a white reflective member is disposed on the outer periphery of the plurality of light-emitting elements, and members containing a phosphor are disposed on the plurality of light-emitting elements.

SUMMARY

It is an object of the present disclosure to provide a light source and a light-emitting module having a good appearance in which an outer peripheral portion of the light source is hard to be visually recognized when the light source is viewed from a light-emitting surface side.

A light source according to the present disclosure includes a plurality of light-emitting elements, a covering member, and a plurality of light-transmissive members. The covering member is disposed between adjacent ones of the plurality of light-emitting elements and on an outer periphery surrounding an entirety of the plurality of light-emitting elements with upper surfaces of the plurality of light-emitting elements being exposed from the covering member. The covering member collectively holds the plurality of light-emitting elements. The plurality of light-transmissive members include a plurality of first light-transmissive members disposed on respective ones of the plurality of light-emitting elements, and at least one second light-transmissive member disposed on the covering member located on the outer periphery, the at least one second light-transmissive member having a thickness smaller than a thickness of each of the plurality of first light-transmissive members.

With the embodiment of the present disclosure, it is possible to provide a light source and a light-emitting module having a good appearance in which an outer peripheral portion of the light source is hard to be visually recognized when the light source is viewed from a light-emitting surface side.

### BRIEF DESCRIPTION OF THE DRAWINGS

FIG. 1A is a schematic top view illustrating a light source of one embodiment of the present disclosure.

FIG. 1B is a schematic cross-sectional view taken along a line IB-IB in FIG. 1A

FIG. 1C is a schematic cross-sectional view illustrating a modified example of the light source in FIG. 1A.

FIG. 1D is a schematic cross-sectional view illustrating another modified example of the light source in FIG. 1A.

FIG. 1E is a schematic cross-sectional view illustrating yet another modified example of the light source in FIG. 1A.

FIG. 1F is a schematic cross-sectional view illustrating yet another modified example of the light source in FIG. 1A.

FIG. 1G is a schematic cross-sectional view illustrating yet another modified example of the light source in FIG. 1A.

FIG. 2 is a schematic top view for describing an arrangement of light-emitting elements of a light source of one embodiment.

FIG. 3A is a schematic top view illustrating a modified example of a light-transmissive member of the light source of one embodiment.

FIG. 3B is a schematic top view illustrating another modified example of the light-transmissive member of the light source of one embodiment.

FIG. 3C is a schematic top view illustrating yet another modified example of the light-transmissive member of the light source of one embodiment.

FIG. 3D is a schematic top view illustrating yet another modified example of the light-transmissive member of the light source of one embodiment.

FIG. 4 is a schematic cross-sectional view illustrating another example of the light source of one embodiment.

FIG. 5 is a schematic cross-sectional view illustrating yet another example of the light source of one embodiment.

FIG. 6A is a manufacturing process diagram for describing a manufacturing method of the light source of one embodiment.

FIG. 6B is a manufacturing process diagram for describing the manufacturing method of the light source of one embodiment.

FIG. 6C is a manufacturing process diagram for describing the manufacturing method of the light source of one embodiment.

FIG. 6D is a manufacturing process diagram for describing the manufacturing method of the light source of one embodiment.

FIG. 6E is a manufacturing process diagram for describing the manufacturing method of the light source of one embodiment.

FIG. 6F is a manufacturing process diagram for describing the manufacturing method of the light source of one embodiment.

FIG. 6G is a manufacturing process diagram for describing the manufacturing method of the light source of one embodiment.

FIG. 6H is a manufacturing process diagram for describing the manufacturing method of the light source of one embodiment.

FIG. 6I is a manufacturing process diagram for describing the manufacturing method of the light source of one embodiment.

FIG. 6J is a manufacturing process diagram for describing the manufacturing method of the light source of one embodiment.

FIG. 6K is a manufacturing process diagram for describing the manufacturing method of the light source of one embodiment.

FIG. 7 is a schematic cross-sectional view illustrating a light-emitting module of one embodiment of the present disclosure.

### DETAILED DESCRIPTION OF EMBODIMENTS

Hereinafter, an embodiment for carrying out the present disclosure will be described with reference to the drawings. However, the following embodiments are exemplifications for embodying the technical concept of the present invention, and the present invention is not limited to the description below. The sizes, positional relationship, or the like of members illustrated in each of the drawings may be exaggerated for clarity of description. As a cross-sectional view, an end view illustrating only a cut surface is sometimes used. The same names and reference signs denote members that are the same as or of the same quality in principle, and redundant description thereof is omitted as appropriate.

In the present specification, the terms such as “covering” and “cover” imply not only a case of direct covering, but also a case of indirect covering (for example, covering via another member). A light-emitting surface or a light-extracting surface refers to a surface on a light emission surface side of a light-emitting element, that is, an upper surface of a light source. The terms “substantially parallel” and “substantially perpendicular” mean that an inclination of about +5 degrees is allowed.

Light Source

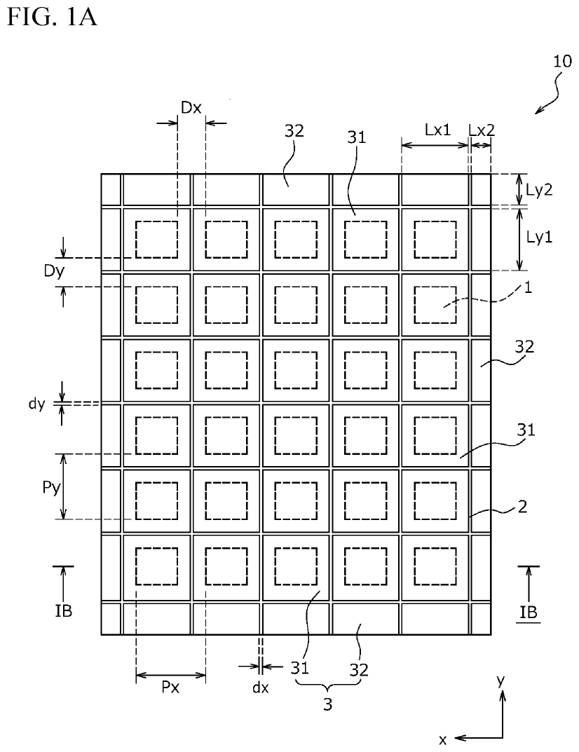

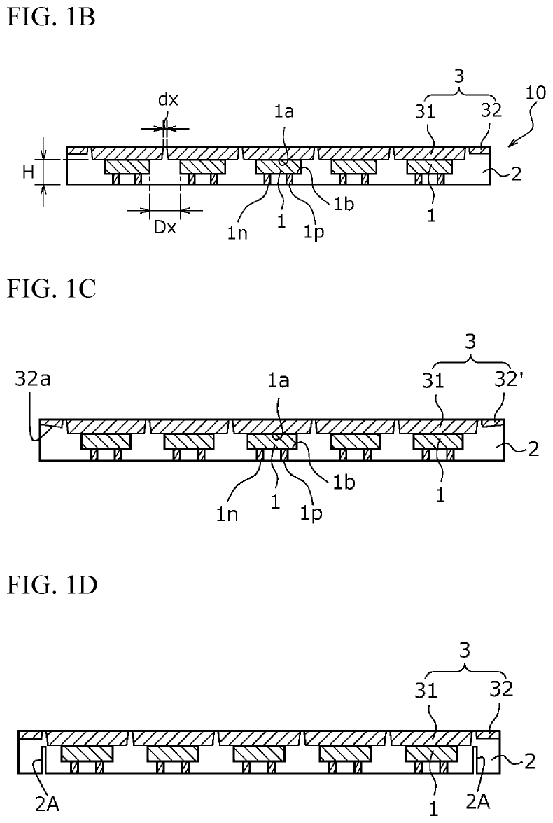

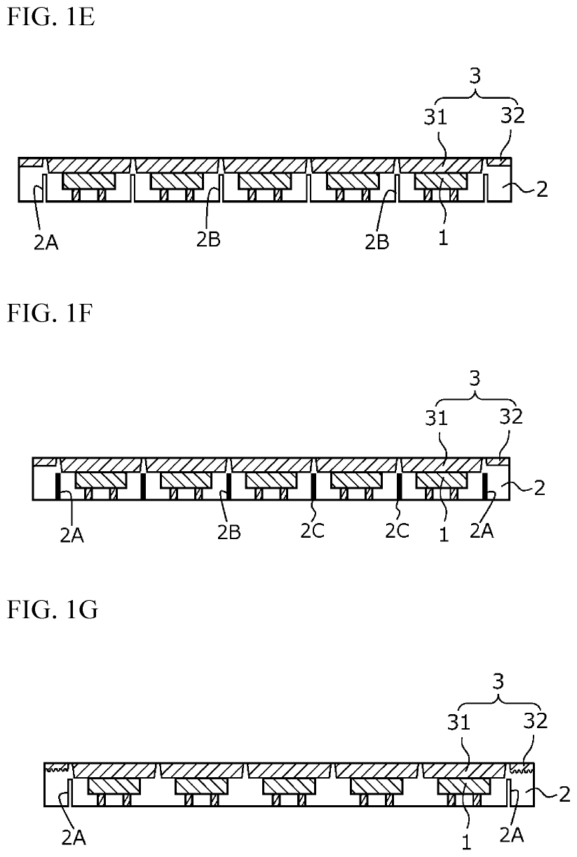

As illustrated in FIGS. 1A and 1B, a light source 10 of one embodiment includes a plurality of light-emitting elements 1, a covering member 2 that collectively holds the plurality of light-emitting elements 1, and a plurality of light-transmissive members 3.

Here, the covering member 2 is disposed between the plurality of light-emitting elements 1 and on an outer periphery surrounding the entirety of the plurality of light-emitting elements with upper surfaces of the plurality of light-emitting elements 1 exposed from the covering member 2, whereby the covering member 2 collectively holds the plurality of light-emitting elements 1. The plurality of light-transmissive members 3 include a plurality of first light-transmissive members 31 disposed on the respective plurality of light-emitting elements 1, and a second light-transmissive member 32 disposed on the covering member 2 located on the outer periphery surrounding the entirety of the plurality of light-emitting elements 1. On the upper surface of the light source 10, at least one second light-transmissive member 32 is disposed on the outer side with respect to the first light-transmissive members 31. The second light-transmissive member 32 has a thickness smaller than a thickness of the first light-transmissive member 31.

With such a disposition of the members, when the light source is not lighting, the covering member on the outer periphery of the light source is hard to be visually recognized when viewed from a light-emitting surface side, and an appearance color of the upper surface of the light source can be substantially uniform. Furthermore, by making the thickness of the second light-transmissive member 32 smaller than the thickness of the first light-transmissive member 31, it is possible to reduce transmission of external light from an upper surface to a lateral surface of the second light-transmissive member 32 when the light source is not lighting. Accordingly, appearance colors of the first light-transmissive member 31 and the second light-transmissive member 32 when the light source is not lighting can be made closer to each other. As a result, when viewed from the light-extracting surface, a substantially uniform appearance color can be obtained over the entire light-extracting surface of the light source regardless of the presence or absence of the light-emitting element immediately below the light-transmissive members. Accordingly, the outer peripheral portion of the light source becomes hard to be visually recognized, and an appearance through a lens can be improved.

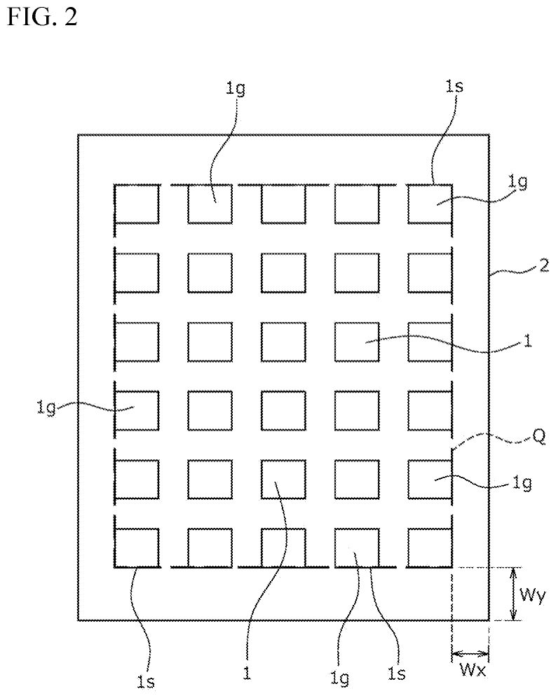

In the present disclosure, as illustrated in FIG. 2, the outer periphery of the entirety of the plurality of light-emitting elements 1 means a portion surrounding an outline (broken line Q) connecting lateral surfaces Is on outer sides of light-emitting elements 1g located on the outer side among the plurality of light-emitting elements disposed in a matrix in a plan view (that is, when viewed from the light-extracting surface side). In other words, it means a region that is a portion on the outer side of the outline (broken line Q) surrounding all of the plurality of light-emitting elements 1 and extends to an end portion of the covering member 2 described later in a plan view. Note that FIG. 2 is a schematic top view for describing the arrangement of the light-emitting elements 1 in the light source 10, and the light-transmissive members 3 are omitted in FIG. 2.

### Light-Emitting Element 1

The plurality of light-emitting elements 1 are arranged two-dimensionally. The plurality of light-emitting elements 1 may be disposed randomly, but are preferably disposed regularly, and are more preferably arranged in a matrix. For example, they are preferably arranged two-dimensionally and regularly along two directions. The arrangement pitch in each direction may be different. For example, the plurality of light-emitting elements 1 may be arranged such that an interval therebetween increases from the center toward the outer periphery. In particular, as illustrated in FIG. 1A, it is preferable that the plurality of light-emitting elements 1 are regularly disposed at equal intervals along the x direction and the y direction orthogonal to each other. In FIG. 1A, for example, 5×6 light-emitting elements 1 are arranged, but the number of the light-emitting elements 1 that are arranged may be any of various numbers such as 5×5, 7×7, and 7×9. The arrangement pitch of the light-emitting elements can be appropriately set depending on the size of the light-emitting element, the size of the first light-transmissive member, and the like. For example, when the length in the x direction, such as one side or the diameter, of the light-emitting element is in a range from 100 μm to 1000 μm, the pitch Px in the x direction may be in a range from 110 μm to 2000 μm. Similarly, the pitch Py in the y direction may be in a range from 110 μm to 2000 μm. Distances Dx and Dy may be different or may be the same.

The plurality of light-emitting elements 1 can be independently lighted individually or in groups.

For the light-emitting element 1, which is a semiconductor light-emitting element, a known light-emitting element, such as a semiconductor laser or a light-emitting diode, can be used. For example, the light-emitting element 1 is a light-emitting diode. For the wavelengths of lights emitted from the light-emitting elements 1, any wavelength can be selected. For example, as a light-emitting element that emits light having a blue-color to green-color wavelength, an element using ZnSe, a nitride-based semiconductor (InₓAl_{y}Ga_{1-x-y}N, 0≤x, 0≤y, x+y<1), or GaP can be used. In addition, as a light-emitting element that emits light having a wavelength of red light, a semiconductor light-emitting element including a semiconductor, such as GaAlAs or AlInGaP, can be used. Furthermore, a semiconductor light-emitting element formed of a material other than the above can be used for the light-emitting element 1. The composition of the semiconductor, and the light emission color, size, number, and the like of the light-emitting elements used can be selected appropriately according to the purpose or design specification. All of the plurality of light-emitting elements may emit light having the same wavelength, or a part or all of the light-emitting elements may emit lights having different wavelengths.

For example, the light-emitting element 1 includes a semiconductor layered body. The semiconductor layered body includes an active layer, and an n-type semiconductor layer and a p-type semiconductor layer between which the active layer is sandwiched. Any of various emission wavelengths can be selected depending on a material for the semiconductor and/or the degree of mixed crystals of the semiconductor. The light-emitting element 1 may include a light-transmissive support substrate that supports the semiconductor layered body.

In the light-emitting element 1, a negative electrode In and a positive electrode 1p are electrically connected to the n-type semiconductor layer and the p-type semiconductor layer, respectively. The light-emitting element 1 has an upper surface la as a main light emission surface and a lower surface 1b located on a side opposite to the upper surface la. In a case in which the semiconductor layered body includes the support substrate, the support substrate may constitute the upper surface la of the light-emitting element 1. In addition, a lateral surface is provided between the upper surface and the lower surface, that is, adjacent to both the upper surface and the lower surface. The light-emitting element 1 may include positive and negative electrodes on the same surface side, or may include positive and negative electrodes on different surfaces. In particular, the light-emitting element 1 preferably includes the positive electrode 1p and the negative electrode In on the lower surface 1b. Such a disposition of the electrodes makes it possible to mount the light-emitting elements on a mounting substrate by flip-chip mounting.

The planar shape of the light-emitting element may be a polygonal shape, such as a triangular shape, a quadrangular shape, or a hexagonal shape, or may be a circular shape, an elliptical shape, or the like, but is preferably a rectangular shape. The size of the light-emitting element can be appropriately set depending on desired performance or the like. For example, the shape of the upper surface la is a rectangle with a size of 100 μm or greater and 1000 μm or less×100 μm or greater and 1000 μm or less, and preferably a rectangle with a size of 150 μm or greater and 500 μm or less×150 μm or greater and 500 μm or less. Accordingly, a light source including the plurality of light-emitting elements can be further downsized.

For example, the plurality of light-emitting elements 1 each preferably has a rectangular shape in a plan view, and are disposed in a rectangular shape as a whole. A part or all of the plurality of light-emitting elements 1 may have different sizes, shapes, or the like in a plan view. The thicknesses of the plurality of light-emitting elements 1 (that is, the total thickness of the semiconductor layered body and the positive and negative electrodes: H in FIG. 1B) may be different from each other, but are preferably the same as each other.

### Covering Member 2

The covering member 2 has a function of protecting the plurality of light-emitting elements 1. In addition, the covering member 2 preferably has a function of reflecting lights emitted from the lateral surfaces of the light-emitting elements 1 and guiding the lights to the upper sides of the light-emitting elements 1, that is, the light-emitting surface side of the light source. Accordingly, the use efficiency of the lights emitted from the light-emitting elements 1 can be improved. The covering member 2 is disposed between the plurality of light-emitting elements 1 and on the outer periphery of the entirety of the plurality of light-emitting elements 1 with upper surfaces of the plurality of light-emitting elements 1 exposed from the covering member 2. In other words, the light emission surfaces of the light-emitting elements 1 are exposed. Furthermore, the covering member 2 preferably covers the lower surfaces 1b of the light-emitting elements 1 with parts of the positive electrodes 1p and the negative electrodes In of the light-emitting elements 1 exposed from the covering member 2. Accordingly, the lights emitted from the light-emitting elements 1 can be efficiently extracted from the light emission surfaces. That is, the covering member 2 can constitute a part of the lower surface of the light source.

When the light-emitting elements 1 are mounted on the mounting substrate, particularly when flip-chip mounting is performed, the covering member 2 may be disposed so as to fill spaces between the light-emitting elements 1 and the mounting substrate, that is, spaces between the lower surfaces 1b of the light-emitting elements 1 other than the parts of the positive electrodes and the negative electrodes and the upper surface of the mounting substrate.

As described above, the covering member 2 is preferably disposed with predetermined widths (Wx and Wy in FIG. 2) respectively in the x direction and the y direction from the lateral surfaces 1s of the light-emitting elements 1 on the outer periphery of the entirety of the plurality of light-emitting elements 1. Here, the predetermined widths Wx and Wy are preferably equal to or greater than the distances Dx and Dy between the plurality of light-emitting elements, for example. Accordingly, the lights emitted from the light-emitting elements located on the outer side among the entire plurality of light-emitting elements can be distributed upward, and light leakage from the lateral surface of the light source can be suppressed. Each of the widths Wx and Wy may be, for example, in a range from 5% to 200% of a corresponding width in the same direction of one of the light-emitting elements.

The covering member 2 is a member having light reflectivity and/or light absorbency. It is especially preferable to have high light reflectivity. Accordingly, lights emitted from the lateral surfaces of the light-emitting elements 1 can be reflected and extracted from the upper surfaces thereof, and the light source having more excellent light extraction efficiency can be obtained. Specifically, the covering member 2 preferably has a reflectance of 60% or more, more preferably 80% or more, with respect to the lights emitted from the light-emitting elements 1.

The covering member 2 includes a resin of a base material and particles of a light reflective material contained in the resin. Examples of the resin include a resin containing one or more of a silicone resin, a modified silicone resin, an epoxy resin, a modified epoxy resin, an acrylic resin, and a fluororesin. Examples of the light reflective material include titanium oxide, aluminum oxide, silicon oxide, zinc oxide, boron nitride, aluminum nitride, and a glass filler. The average particle diameter of the light reflective material is in a range from 0.05 μm to 30 μm, for example. The covering member 2 may further include a light absorbing material, such as pigment, carbon black, titanium black, graphite, or the like, a phosphor, or the like. In the covering member 2 having light reflectivity and/or light absorbency, light reflective materials and/or light-absorbing particles are preferably dispersed to be disposed in the resin.

As illustrated in FIG. 1D, the covering member 2 constitutes a part of the lower surface of the light source, and may include a groove 2A around the outer periphery of the entirety of the plurality of light-emitting elements 1 in the lower surface. In addition, the covering member 2 may include grooves 2B each between corresponding ones of the light-emitting elements 1 in the lower surface of the light source. As illustrated in FIG. 1E, the covering member 2 may include the grooves 2A and 2B around the outer periphery of the entirety of the plurality of light-emitting elements 1 and between corresponding ones of the light-emitting elements 1 in the lower surface of the light source. In this case, all or a part of the grooves may be continuous when viewed from the lower surface side. Furthermore, as illustrated in FIG. 1F, light-blocking members 2C may be provided in the grooves 2A and 2B. Here, it is preferable that the light-blocking member 2C has a higher light absorbency or a higher light reflectivity with respect to the light of the light-emitting elements 1 than that of the covering member 2. By providing the grooves 2A, 2B and/or the light-blocking members 2C, light leakage in the lateral direction when the light-emitting elements are lighting can be reduced.

In the covering member 2, the grooves 2A and 2B can have depths equal to or smaller than the thickness (H in FIG. 1B) of the light-emitting elements 1 so as to be opposed to a part or all of the lateral surfaces of the light-emitting elements 1. In particular, the depths of the grooves 2A and 2B are preferably about equal to the thickness of the light-emitting elements 1. Accordingly, the light leakage in the lateral direction from the light-emitting elements 1 can be further reduced. In addition, the widths of the grooves 2A and 2B can be appropriately set depending on the size of the light source to be obtained, the size of the light-emitting elements 1 used, and the like. In particular, the widths of the grooves 2A and 2B may be equal to or smaller than the distance dx between adjacent ones of the first light-transmissive members 31 in the x direction and the distance dy between adjacent ones of the first light-transmissive members 31 in the y direction. By setting the widths of the grooves 2A and 2B to such values, it is possible to avoid the grooves 2A and 2B from coming into contact with the first light-transmissive members 31 and the second light-transmissive members 32. As a result, even when the grooves 2A and 2B are provided, the covering member 2 can collectively hold the plurality of light-emitting elements 1.

For the light-blocking member 2C, a material similar to that of the covering member 2 described above can be used. Examples thereof include a material containing a larger amount of light reflective material or light-absorbing material than the covering member 2.

### Light-Transmissive Member 3

The light-transmissive member 3 includes a plurality of the first light-transmissive members 31 disposed on the respective plurality of light-emitting elements 1, and the second light-transmissive member 32 disposed on the covering member 2 located on the outer side of the outer periphery of the entirety of the light-emitting elements 1. Note that the number of first light-transmissive members 31 and the number of light-emitting elements 1 included in the light source 10 may be the same or different.

The size of the first light-transmissive member 31 may be smaller than, equal to, or larger than that of the light emission surface of the light-emitting element 1 (that is, the upper surface of the light-emitting element 1) on which the first light-transmissive member 31 is disposed, in a plan view. In particular, the size of the first light-transmissive member 31 is preferably equal to or larger than that of the upper surface of the light-emitting element 1, and as illustrated in FIG. 1A, it is more preferable for the first light-transmissive member 31 to have a larger size than the upper surface of the light-emitting element 1 and to be disposed so as to include the upper surface of the light-emitting element in a plan view. The lower surface of the first light-transmissive member 31 preferably has a shape that is the same as or similar to that of the upper surface of the light-emitting element 1. In this case, the planar area of the first light-transmissive member 31 is, for example, in a range from 100% to 150% , and preferably in a range from 100% to 130% of the planar area of the upper surface of the light-emitting element 1. The first light-transmissive members 31 are disposed on the plurality of light-emitting elements, and are preferably arranged as in the arrangement of the plurality of light-emitting elements 1. For example, as illustrated in FIG. 1B, the distance dx between adjacent ones of the first light-transmissive members 31 in the x direction and the distance dy between adjacent ones of the first light-transmissive members 31 in the y direction are preferably smaller than the distances Dx and Dy between adjacent ones of the light-emitting elements 1, respectively. Accordingly, it is possible to further reduce the regions having low luminance between the light-transmissive members adjacent to each other on the light-emitting surface.

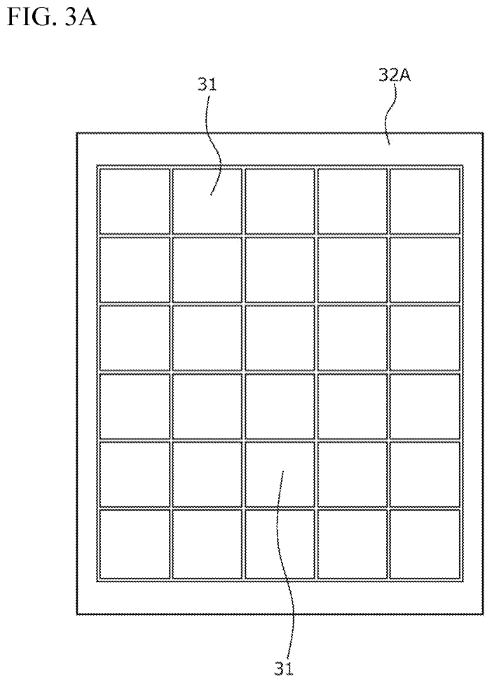

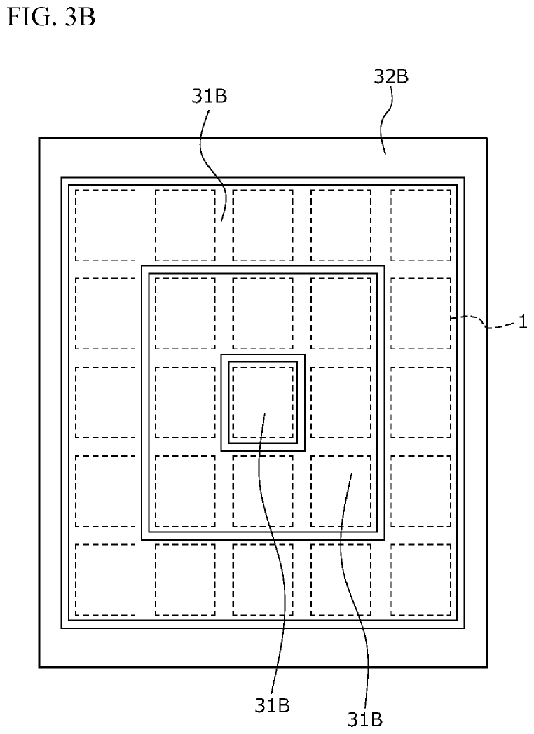

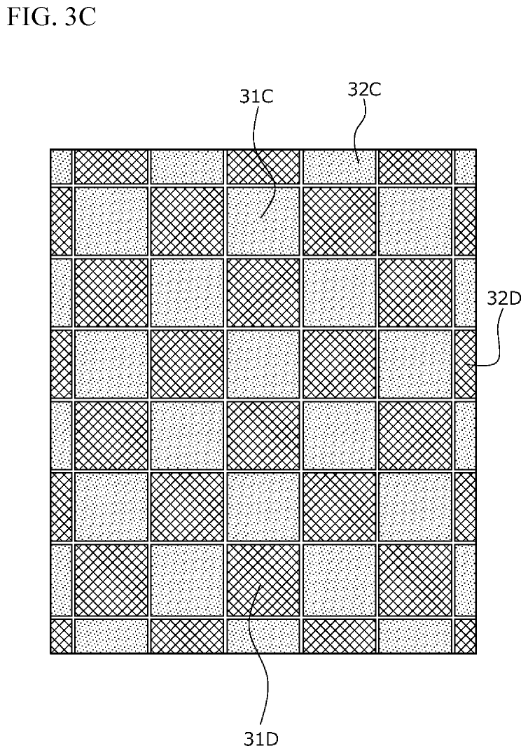

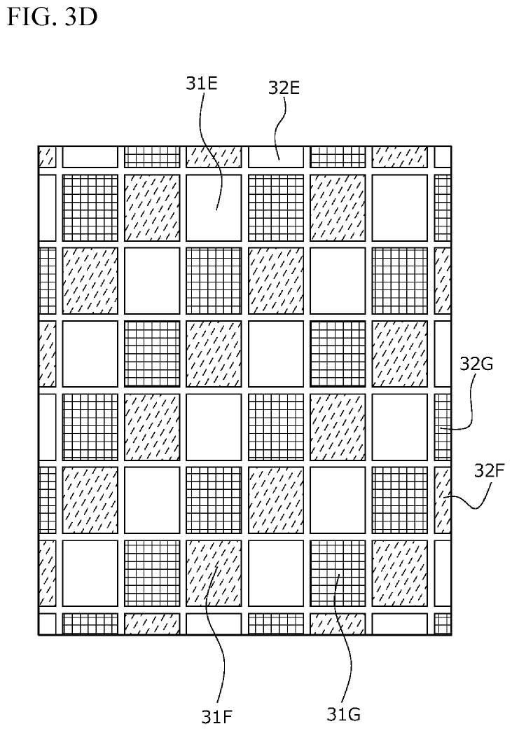

The plurality of first light-transmissive members 31 included in the light source 10 may have the same planar shape and size as illustrated in FIG. 3A, or a part or all of the plurality of first light-transmissive members 31 may have different planar shapes and sizes. For example, as illustrated in FIG. 3B, the first light-transmissive member 31B may include one first light-transmissive member disposed on one light-emitting element 1 at the center, one first light-transmissive member disposed on light-emitting elements 1 adjacent to the light-emitting element 1 at the center, that is, the light-emitting elements 1 surrounding the one light-emitting element 1 at the center, and one first light-transmissive member disposed on the light-emitting elements 1 surrounding the light-emitting elements 1 surrounding the light-emitting element 1 at the center.

The plurality of first light-transmissive members 31 are preferably arranged in a rectangular shape as a whole in a plan view, as in the arrangement of the light-emitting elements 1. Furthermore, the plurality of light-transmissive members 3 including one or more second light-transmissive members 32 are preferably arranged in a rectangular shape as a whole.

A part or all of the first light-transmissive members 31 may have different thicknesses, but it is preferable for all of the first light-transmissive members 31 to have the same thickness. The thickness of the first light-transmissive members 31 can be appropriately adjusted depending on the features to be obtained, and is, for example, in a range from 50 μm to 200 μm.

At least one second light-transmissive member 32 is disposed on the covering member 2 disposed on the outer periphery of the entirety of the light-emitting elements 1, or a plurality of the second light-transmissive members 32 may be disposed thereon. In other words, the second light-transmissive member 32 is not disposed on the light-emitting elements 1. For example, as illustrated in FIG. 1A, on the outer periphery of the entirety of the light-emitting elements 1, the second light-transmissive member 32 may be arranged in the x direction and the y direction on the covering member 2 disposed as in the arrangement of the first light-transmissive members 31 disposed on the light-emitting elements 1. In this case, the second light-transmissive member 32 may have the same shape and size as the first light-transmissive member 31 in a plan view, or may have a shape and size including a part of the shape of the first light-transmissive member 31 in a plan view.

The second light-transmissive member 32 can have a shape in which the width in the arrangement direction is different from that of the first light-transmissive member 31 disposed adjacent to the second light-transmissive member 32 in a plan view. In this case, the length of one side in the x direction of the second light-transmissive member 32 adjacent to the first light-transmissive member 31 in the x direction is preferably in a range from 5% to 100% and more preferably in a range from 25% to 75% of the length of one side in the x direction of the first light-transmissive member 31 disposed adjacent to the second light-transmissive member 32, in a plan view. In this case, the length of one side in the y direction of the second light-transmissive member 32 adjacent to the first light-transmissive member 31 in the x direction is preferably 100% or more of the length of one side in the y direction of the first light-transmissive member 31 disposed adjacent to the second light-transmissive member 32. For example, as illustrated in FIG. 1A, the length Lx2 of one side in the x direction of the second light-transmissive member 32 is preferably in a range from 5% to 100% of the length Lx1 of one side in the x direction of the first light-transmissive member 31 disposed adjacent to the second light-transmissive member 32 in the x direction. Similarly, the length Ly2 of the second light-transmissive member 32 in the y direction is preferably in a range from 5% to 100% of the length Ly1 of the first light-transmissive member 31 in the y direction disposed adjacent to the second light-transmissive member 32 in the y direction. Accordingly, the spread of light in the x direction in the first light-transmissive members 31 adjacent to the second light-transmissive member 32 can be approximated to the spread in the x direction in the first light-transmissive members 31 not adjacent to the second light-transmissive member 32 (that is, adjacent to the first light-transmissive members 31).

Similarly, from the viewpoint of approximating the spreads in the x direction and/or the y direction of the first light-transmissive members 31 adjacent to the second light-transmissive member 32 and the first light-transmissive members 31 not adjacent to the second light-transmissive member 32 (that is, adjacent to the first light-transmissive members 31), the distance between the first light-transmissive member 31 and the second light-transmissive member 32 adjacent to each other in the x direction and/or the y direction on the light-emitting surface of the light source 10 is preferably the same as the distance dx and/or the distance dy between the first light-transmissive members 31 adjacent to each other in the x direction and/or the y direction.

As illustrated in FIGS. 3A and 3B, only one second light-transmissive member 32A or 32B may be disposed on the covering member 2 disposed on the outer periphery of the entirety of the light-emitting elements 1, so as to surround the entirety of the light-emitting elements 1. In this case, the second light-transmissive members 32A and 32B have different shapes and sizes from the first light-transmissive member 31 in a plan view.

When the plurality of first light-transmissive members 31 are disposed in a rectangular shape as a whole in a plan view, one or more second light-transmissive members 32 can be disposed along the outer periphery of the rectangular shape. The second light-transmissive member 32 has a thickness smaller than that of the first light-transmissive member. In this case, a part of the second light-transmissive member 32 may have a thickness smaller than that of the first light-transmissive members 31, or the entire second light-transmissive member 32 may have a thickness smaller than that of the first light-transmissive members 31. In addition, a part of or the entirety of the second light-transmissive member 32 may have different thicknesses, or the entire second light-transmissive member 32 may have the same thickness. The thickness of the second light-transmissive member 32 is, for example, in a range from 10% to 90% , preferably in a range from 30% to 80% , and more preferably in a range from 40% to 70% of the thickness of the first light-transmissive member 31. Specifically, the thickness of the second light-transmissive member 32 can be appropriately adjusted depending on the features to be obtained, and is, for example, in a range from 15 μm to 160 μm.

In the light source 10, the upper surfaces of the plurality of first light-transmissive members 31 and the second light-transmissive member 32 are each exposed from the covering member 2. On the upper surface of the light source 10, the covering member 2 is preferably disposed between the first light-transmissive members 31 and the second light-transmissive member 32 adjacent to each other. In this case, the opposed lateral surfaces of the first light-transmissive members 31 and the second light-transmissive member 32 adjacent to each other may be only partially covered with the covering member 2 in the thickness direction, but are preferably entirely covered with the covering member 2 in the thickness direction. In other words, in the light source 10, the upper surface of the covering member 2 is preferably flush with the upper surfaces of the plurality of first light-transmissive members 31 and the second light-transmissive member 32. A lateral surface of the second light-transmissive member 32 that is not opposed to the first light-transmissive member 31 or another second light-transmissive member 32, that is, a lateral surface facing the outer side of the light source 10, need not be covered with the covering member 2. In other words, the second light-transmissive member 32 can have a lateral surface exposed from the covering member 2 that constitutes an outer lateral surface of the light source 10.

The light-transmissive member 3 is a member that transmits at least a part of the light emitted from the light-emitting element 1, and examples thereof include a member that transmits 60% or more of the light emitted from the light-emitting element 1, and it is preferably a member that transmits 70% or more, 75% or more, or 80% or more of the light. The shape is preferably a plate shape.

Specifically, the light-transmissive member 3 has an upper surface serving as a light-emitting surface of the light source 10, a lower surface on a side opposite to the upper surface (that is, a surface on the covering member side), and a lateral surface between the upper surface and the lower surface. The lower surface of the first light-transmissive member 31 is disposed opposed to the upper surface of the light-emitting element 1, and the lower surface of the second light-transmissive member 32 is disposed opposed to the upper surface of the covering member 2 located on the outer periphery of the entirety of the light-emitting elements 1. The upper surface and the lower surface of the first light-transmissive member 31 are preferably substantially flat and parallel to each other. The upper surface and the lower surface of the second light-transmissive member 32 may be flat surfaces substantially parallel to each other, or the lower surface of the second light-transmissive member 32 may be inclined with respect to the upper surface thereof. For example, as illustrated in FIG. 1C, a lower surface of a second light-transmissive member 32′ may include an inclined portion 32a. As illustrated in FIG. 1G, the lower surface of the second light-transmissive member 32 may have protrusions and recesses. When the lower surface of the second light-transmissive member 32′ includes the inclined portion 32a that is inclined with respect to the upper surface of the second light-transmissive member 32, the inclined portion 32a is preferably inclined such that the thickness becomes smaller toward the side opposite to the first light-transmissive member 31, that is, toward the outer side of the light source 10. Accordingly, light leakage toward the outer side of the light source 10 can be reduced. The inclined portion 32a of the lower surface of the second light-transmissive member 32 may be disposed on a part of the lower surface or may be disposed over the entire lower surface. The lateral surface of the light-transmissive member 3 may be a surface perpendicular to the upper surface and/or the lower surface thereof, or may be a surface inclined with respect to the upper surface and/or the lower surface. In particular, the lateral surface of the light-transmissive member 3 is preferably a lateral surface substantially perpendicular to the upper surface.

The light-transmissive member 3 can be formed of, for example, a light-transmissive resin, glass, or a ceramic. A resin containing one or more of a silicone resin, a modified silicone resin, an epoxy resin, a modified epoxy resin, an acrylic resin, and a fluororesin can be used for the light-transmissive resin.

In addition, the light-transmissive member 3 can contain a phosphor that can convert the wavelength of at least a part of incident light. Examples of the light-transmissive member 3 containing a phosphor include a sintered compact of a phosphor and a light-transmissive resin, glass, ceramic, or the like containing phosphor powder. Another example is a light-transmissive plate having a surface provided with a layer containing a phosphor; the light-transmissive plate is a molded body of a light-transmissive resin, glass, a ceramic, or the like.

As the phosphor, for example, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAION-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a III-V group quantum dot (for example, InP), a quantum dot having a chalcopyrite structure (for example, (Ag,Cu)(In,Ga)(S,Se)2), or the like can be used.

A part or all of the plurality of light-transmissive members 3 may be formed of only a light-transmissive material, or a part or all of the plurality of light-transmissive members 3 may contain a phosphor. In this case, a part or all of the plurality of light-transmissive members 3 may contain the same phosphor, or a part or all of the light-transmissive members 3 may contain different phosphors. All of the plurality of light-transmissive members 3 may contain a phosphor that is excited by blue light to emit yellow light. In addition, a part of the plurality of light-transmissive members 3 may contain a phosphor that is excited by blue light to emit yellow light, and another part may contain a phosphor that is excited by blue light to emit orange light. By adjusting the type or content of the phosphor contained in the light-transmissive member 3, light of a desired color can be emitted from the upper surface of the first light-transmissive member 31. In particular, when the emission peak wavelengths of the plurality of light-emitting elements 1 are in a range from 400 nm to 490 nm, the plurality of light-transmissive members 3 preferably contain phosphors whose emission peak wavelengths are in a range from 520 nm to 680 nm. Accordingly, the light source 10 that emits white light can be obtained. Since the second light-transmissive member 32 contains a phosphor similar to that of the first light-transmissive member 31, the appearance color of the phosphor is visually recognized as the appearance color of the light-transmissive member 3 when the light source 10 is not lighting, and the appearance color of the region immediately above the plurality of light-emitting elements 1 can be made substantially equivalent to the appearance color of the region around the outer periphery of the entirety of the plurality of light-emitting elements 1.

As illustrated in FIG. 3C, in the light source including the plurality of light-emitting elements 1 that emit blue light, first light-transmissive members 31C and first light-transmissive members 31D having upper surfaces from which lights of different emission colors exit can be alternately arranged in the x direction and the y direction. For example, the first light-transmissive member 31C contains a phosphor that is excited by blue light to emit yellow light, and white light exits from the upper surface of the first light-transmissive member 31C. The first light-transmissive member 31D contains a phosphor that is excited by blue light to emit red light and a phosphor that is excited by blue light to emit yellow light, and orange light exits from the upper surface of the first light-transmissive member 31D. Thus, it is possible to obtain a light source that can adjust the emission color in a range from white light to orange light. In this case, it is preferable that second light-transmissive members 32C and 32D are also similarly arranged alternately in the x direction and the y direction so as to correspond to the first light-transmissive members 31C and 31D. In this case, for example, the second light-transmissive member 32C contains a phosphor that emits yellow light similarly to the first light-transmissive member 31C, and the second light-transmissive member 32D contains a phosphor that emits red light and a phosphor that emits yellow light similarly to the first light-transmissive member 31D.

In addition, as illustrated in FIG. 3D, in the light source including the plurality of light-emitting elements 1 that emit blue light, first light-transmissive members 31E, first light-transmissive members 31F, and first light-transmissive members 31G having upper surfaces from which lights of mutually different emission colors exit can be alternately arranged in the x direction and the y direction. The first light-transmissive member 31E does not contain a phosphor, and blue light exits from the upper surface of the first light-transmissive member 31E. The first light-transmissive member 31F contains a phosphor that is excited by blue light to emit red light, and red light exits from the upper surface of the first light-transmissive member 31F. The first light-transmissive member 31G contains a phosphor that is excited by blue light to emit green light, and green light exits from the upper surface of the first light-transmissive member 31G. Accordingly, blue, green, and red lights are emitted, such that a light source that can perform multi-color display can be obtained. In this case, it is preferable that second light-transmissive members 32E, 32F, and 32G be similarly sequentially arranged in the x direction and the y direction, corresponding to the first light-transmissive members 31C, 31E, and 31F. In this case, the second light-transmissive member 32E does not contain a phosphor similarly to the first light-transmissive member 31E, the second light-transmissive member 32F contains a phosphor that emits red light similarly to the first light-transmissive member 31F, and the second light-transmissive member 32G contains a phosphor that emits green light similarly to the first light-transmissive member 31G.

For the distance between adjacent ones of the light-transmissive members 3, the distance between adjacent ones of the first light-transmissive members, the distance between one of the first light-transmissive members and one of the second light-transmissive members that are adjacent to each other, and the distance between adjacent ones of the second light-transmissive members may be different or the same. For example, the distance is in a range from 10 μm to 200 μm, and is preferably in a range from 20 μm to 100 μm.

By disposing the plurality of light-transmissive members 3 as described above, that is, by disposing the first light-transmissive members 31 on the plurality of light-emitting elements 1 and the second light-transmissive members 32 on the light-blocking members located on the outer periphery of the entirety of the plurality of light-emitting elements 1, it is possible to reduce or eliminate the area of the covering member 2 exposed on the outer periphery of the light source when the light source is visually recognized from the light-emitting surface side of the light source. As a result, for example, when the light source is visually recognized from the outside, the covering member 2 on the outer periphery becomes inconspicuous, and design of the light source can be improved. In particular, it is possible to reduce the difference in color between the covering member 2 and the light-transmissive members 3 when the light source 10 is not lighting. In addition, with respect to light incident from the outer side when the light source 10 is not lighting, light leakage in the lateral direction from the second light-transmissive members disposed on the outer periphery can be reduced due to the thicknesses of the second light-transmissive members. Therefore, when viewed from the light-extracting surface, regardless of the presence or absence of the light-emitting elements immediately below the light-transmissive members, it is possible to obtain a substantially uniform appearance color on the entire surface of the light-extracting surface side of the light source, and the design can be improved.

Furthermore, since the light source 10 includes the second light-transmissive members 32, on the upper surface of the light source 10, the covering member 2 surrounding the upper surfaces of the first light-transmissive members 31 disposed on the light-emitting elements 1 located on the inner side and the covering member 2 surrounding the upper surfaces of the first light-transmissive members 31 disposed on the light-emitting elements 1 located on the outer side can have substantially the same width. Accordingly, the spreads of respective lights passing through the first light-transmissive members 31 located on the inner side and the outer side can be approximated to each other. That is, since the light source 10 includes the second light-transmissive members 32, the lights emitted from the light-emitting elements 1 located on the outer side are blocked by the covering member 2 located on the outer periphery of the entirety of the light-emitting elements 1, and it is possible to reduce occurrence of variation in light distribution on the light-emitting surface side of the light source 10. As described above, according to the present embodiment, it is possible to obtain a light source in which, when a specific light-emitting element among the plurality of light-emitting elements is lighted, the distribution of lights that exit from the first light-transmissive members 31 located on the outer side is equivalent to the distribution of lights that exit from the first light-transmissive members 31 located on the inner side. In addition, when the light source is lighting, light leakage in the lateral direction from the second light-transmissive members disposed on the outer periphery can be reduced due to the thicknesses of the second light-transmissive members. Accordingly, it is possible to reduce stray light, such as unnecessary reflection or scattering of light, generated outside a light-emitting region of the light source.

### Third Light-Transmissive Member 4

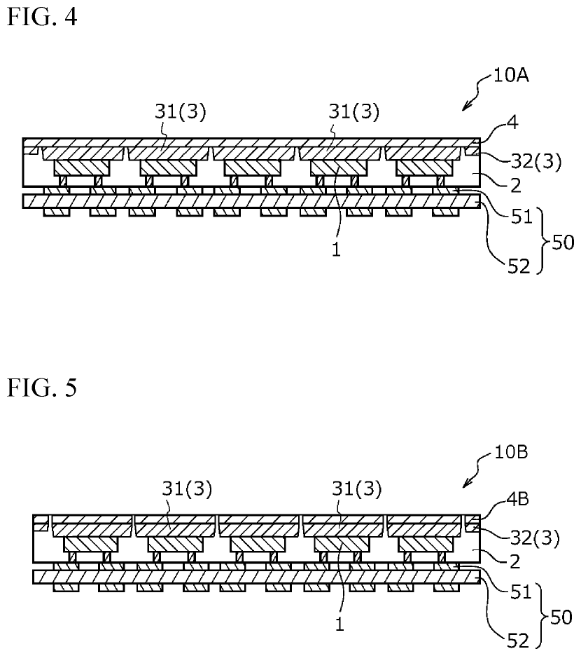

As illustrated in FIGS. 4 and 5, light sources 10A and 10B of embodiments may further include a third light-transmissive member 4 that covers the upper surfaces of the light-transmissive members 3. The third light-transmissive member 4 can be formed of a light-transmissive resin, glass, a ceramic, or the like, similarly to the light-transmissive member 3. A resin containing one or more of a silicone resin, a modified silicone resin, an epoxy resin, a modified epoxy resin, an acrylic resin, and a fluororesin can be used for the light-transmissive resin.

The third light-transmissive member 4 may contain a light-diffusing material. Examples of the light-diffusing material include particles of titanium oxide, aluminum oxide, silicon oxide, zinc oxide, or the like. By providing the third light-transmissive member 4 containing such a light-diffusing material, lights emitted from the light-emitting elements 1 can be diffused and emitted to the outside. Accordingly, it is possible to suppress uneven light emission on the upper surfaces of the light-transmissive members 3.

The third light-transmissive member 4 may be formed using a resin having low absorption for visible light, such as a polycarbonate resin, a polystyrene resin, or a polyethylene resin. The surface of the third light-transmissive member 4 may be flat or may have fine protrusions and recesses or the like.

As illustrated in FIG. 4, the light source 10A of one embodiment includes the third light-transmissive member 4 that integrally covers all of the first light-transmissive members 31 and the second light-transmissive member 32. In this case, the third light-transmissive member 4 wholly covers the upper surface of the light source 10A including the covering member 2 between the light-transmissive members 3. This makes it possible to improve the adhesion between the members.

As illustrated in FIG. 5, the light source 10B of one embodiment includes a plurality of third light-transmissive members 4B that cover the respective upper surfaces of the first light-transmissive members 31 and the second light-transmissive member 32. The plurality of third light-transmissive members 4B are disposed on corresponding ones of the first light-transmissive members 31 and the second light-transmissive member 32. As in the case of the first light-transmissive members 31 and the second light-transmissive member 32, the covering member 2 is preferably disposed between the third light-transmissive members 4B such that the covering member 2 covers the lateral surfaces of each of the third light-transmissive members 4B. Accordingly, unintended light transmission between the third light-transmissive members can be reduced.

A part or all of the plurality of third light-transmissive members 4 may have different thicknesses, or all of the third light-transmissive members 4 may have the same thickness. In particular, it is preferable that all of the third light-transmissive members 4 have substantially the same thickness. The thickness of the third light-transmissive member 4 can be appropriately adjusted depending on the features to be obtained, and is, for example, in a range from 20 μm to 100 μm.

The third light-transmissive member 4 has a function of diffusing and guiding the lights emitted from the light-emitting elements 1. The third light-transmissive member 4 may be a single layer or may have a layered structure including a plurality of layers. The third light-transmissive member 4 has, for example, a total light transmittance (Tr) in a range from 30% to 99% and a diffusivity (D) in a range from 10% to 90% . The third light-transmissive member 4 may have a thickness in a range from 10 μm to 200 μm.

The third light-transmissive member 4 may be in contact with the upper surfaces of the covering member 2 and the light-transmissive members 3, or may be disposed at a distance from the upper surfaces of the covering member 2 and the light-transmissive members 3. In particular, a lower surface of the third light-transmissive member 4 is preferably in direct contact with the upper surfaces of the covering member 2 and the light-transmissive members 3. Accordingly, the lights from the light-emitting elements 1 can be efficiently introduced into the third light-transmissive member 4, and the light extraction efficiency can be improved.

### Wiring Substrate 50

As illustrated in FIGS. 4 and 5, in the light sources 10A and 10B according to embodiments, a plurality of the light-emitting elements 1 may be mounted on a wiring substrate 50. The wiring substrate 50 has, for example, a substantially rectangular parallelepiped shape.

The wiring substrate 50 may include at least a wiring line 51 connected to the light-emitting element 1 on the upper surface thereof, and a base 52 supporting the wiring line 51.

As the base 52, for example, a single material of a ceramic, such as aluminum oxide, aluminum nitride, silicon nitride, or mullite, a resin, such as an epoxy resin, a silicone resin, a modified epoxy resin, a modified silicone resin, a urethane resin, a phenol resin, a polyimide resin, a BT resin, or polyphthalamide, a semiconductor, such as silicon, or a metal, such as copper or aluminum, or a composite material thereof can be used. In particular, a ceramic having excellent heat dissipation is preferably used. The wiring line 51 includes at least an upper surface wiring line 51 disposed on an upper surface of the base 52. Furthermore, the wiring substrate 50 may include a lower surface wiring line disposed on a lower surface of the base 52 and a wiring line disposed inside the base 52 and/or on a lateral surface of the base 52. Note that the wiring line 51 may be partially different in thickness or the like. Examples of the wiring 51 include metals, such as iron, copper, nickel, aluminum, gold, silver, platinum, titanium, tungsten, and palladium, and alloys containing any of these metals. When the light source 10A or 10B is mounted on the wiring substrate 50, the covering member 2 is preferably also disposed between the wiring substrate 50 and the light-emitting elements 1.

### Manufacturing Method of Light Source

The light source 10 described above can be manufactured by preparing a light-transmissive sheet, forming a plurality of groove portions in the light-transmissive sheet, dividing the light-transmissive sheet into a plurality of light-transmissive members, thinning any of the light-transmissive members separated by the groove portions, placing a light-emitting element on each of surfaces of the plurality of light-transmissive members separated by the groove portions and not thinned, disposing a covering member on the light-transmissive members, in the groove portions, and between the light-emitting elements from the light-emitting element side, and singulating the layered body in groups of a plurality of the light-transmissive members and a plurality of the light-emitting elements such that any thinned light-transmissive member is disposed on the outermost periphery.

In addition, after the covering member is disposed, a groove surrounding the entirety of the plurality of light-emitting elements may be formed on the outer side of the outer periphery of the entirety of the plurality of light-emitting elements in the covering member, or grooves may be formed between the plurality of light-emitting elements. Furthermore, light-blocking members may be disposed in these grooves. Conductive films 8 connected to the respective positive electrodes 1p and negative electrodes In of the light-emitting elements 1 exposed from the covering member 2 may be formed on the surface of the covering member 2. By forming such conductive films 8, it is possible to substantially increase the surface areas of the positive electrodes 1p and the negative electrodes In of the light-emitting elements 1 exposed from the covering member 2, and it is possible to improve the connectability to the wiring substrate or the like.

### Preparation of Light-Transmissive Sheet 3a

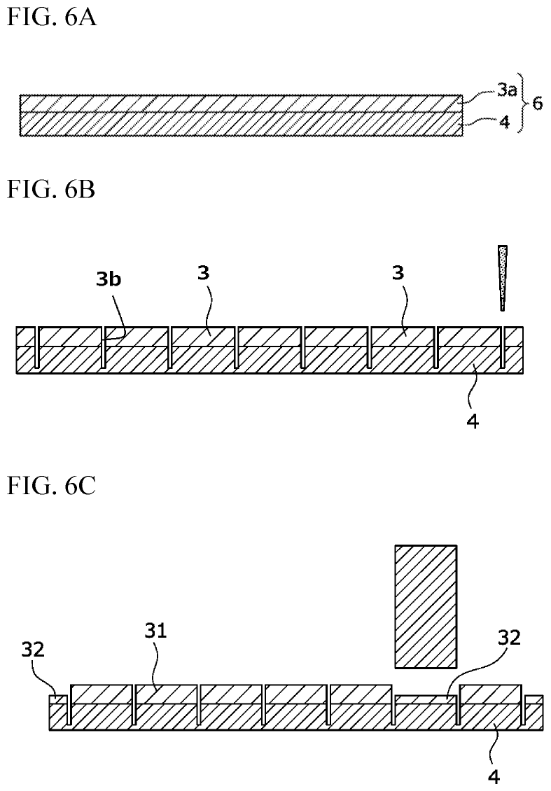

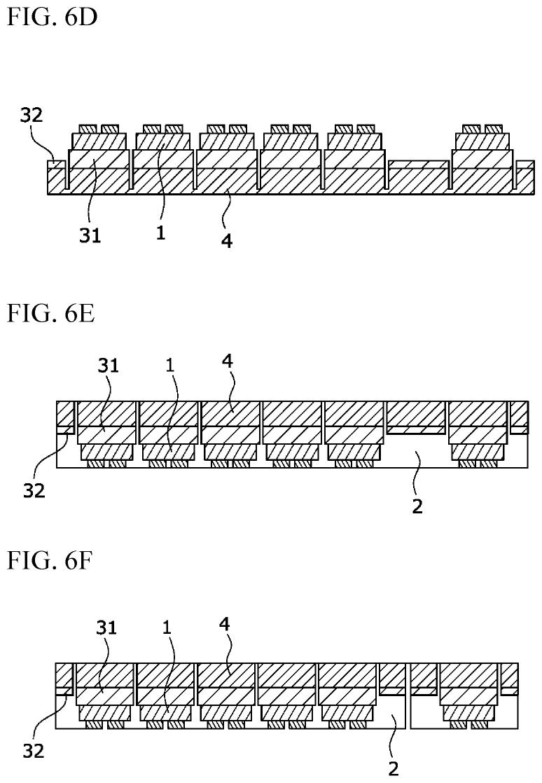

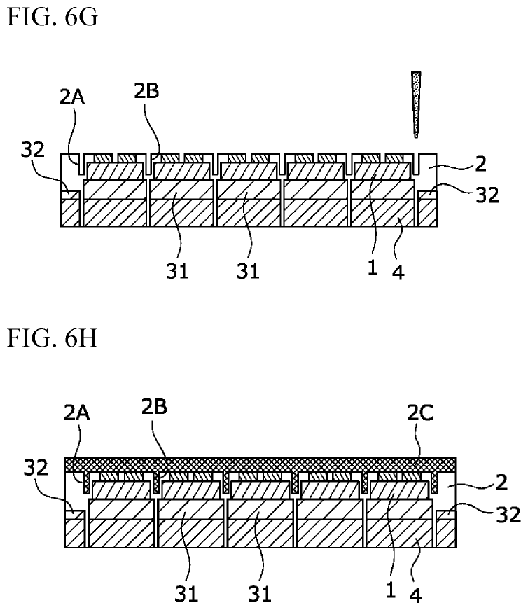

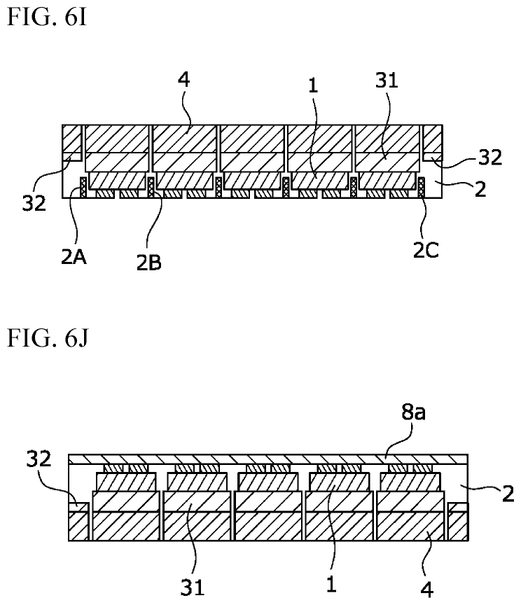

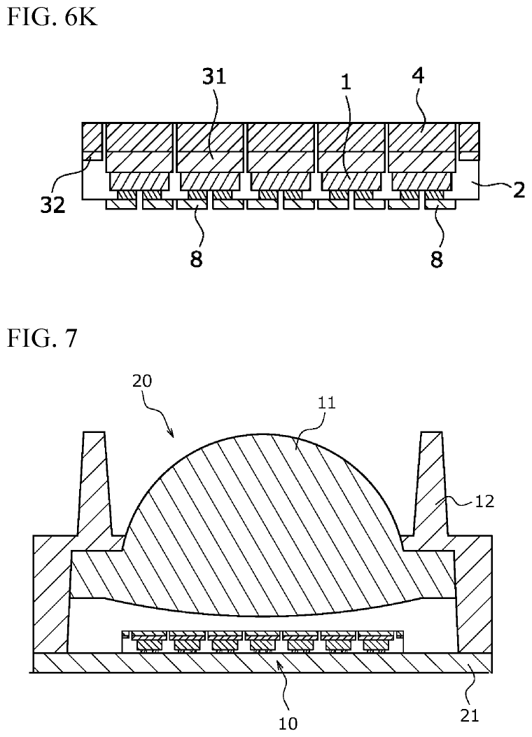

As illustrated in FIG. 6A, a light-transmissive sheet 3a is prepared. The light-transmissive sheet 3a is later singulated into a plurality of the light-transmissive members 3 by the formation of the groove portions. The light-transmissive sheet 3a may be a laminate sheet 6 in which the third light-transmissive member 4 is layered on the light-transmissive sheet 3a, or may be a laminate sheet in which a tape or the like to be removed later, such as a dicing tape, is layered on the light-transmissive sheet 3a. The layers may be integrally layered directly or via a light-transmissive adhesive or the like.

### Formation of Groove Portions in Light-Transmissive Sheet 3a

As illustrated in FIG. 6B, a plurality of groove portions penetrating through the light-transmissive sheet 3a are formed in the light-transmissive sheet 3a to divide the light-transmissive sheet 3a into a plurality of the light-transmissive members 3. When the laminate sheet 6 in which the third light-transmissive member 4 is layered on the light-transmissive sheet 3a is used, groove portions 3b having a depth equal to or larger than the thickness of the light-transmissive sheet 3a are formed from the light-transmissive sheet 3a side. The groove portion 3b preferably has a depth not large enough for penetration through the third light-transmissive member 4 and the like, that is, a depth smaller than the thickness of the laminate sheet 6. Accordingly, the plurality of separated light-transmissive members 3 can be collectively held as the laminate sheet 6. The groove portions 3b may be formed using a blade or the like, or may be formed by etching or the like using a mask member.

### Thinning of Light-Transmissive Member 3

As illustrated in FIG. 6C, among the plurality of light-transmissive members 3 separated by the groove portions 3b, any of the light-transmissive members 3 is thinned. The thinning may be performed by any method known in the art, for example, by scraping the surface of any of the light-transmissive members 3 by polishing, a blade, grinding, or the like. One or a plurality of light-transmissive members 3 disposed on the outer periphery of any number of light-transmissive members 3 used to form one light source are to be thinned. In particular, it is preferable that all of the light-transmissive members 3 disposed on the entire outer periphery of any number of light-transmissive members 3 used to form one light source be thinned. Specific examples thereof include those corresponding to the positions of the second light-transmissive members 32, 32A, and 32B illustrated in FIGS. 1A, 3A, 3B, and the like.

### Disposition of Light-emitting Element 1

As illustrated in FIG. 6D, the light-emitting elements 1 are placed on the surfaces of corresponding ones of the plurality of light-transmissive members 3 that have not been subjected to the thinning process. In this case, the light-emitting elements 1 are disposed such that the light emission surfaces thereof are opposed to corresponding ones of the light-transmissive members 3. The light emission surfaces of the light-emitting elements 1 and corresponding ones of the light-transmissive members 3 may be fixed so as to be in direct contact with each other, or may be fixed using a light-transmissive adhesive or the like.

Note that either the thinning of the light-transmissive member 3 or the disposition of the light-emitting elements 1 may be performed first. For example, after the light-emitting element 1 is disposed over any light-transmissive member obtained by division, the thinning process may be performed on the light-transmissive members 3 over which the light-emitting elements 1 are not disposed.

### Formation of Covering Member 2

Subsequently, the covering member 2 is disposed on the light-transmissive members 3, in the groove portions 3b, and between the light-emitting elements 1. The material of the covering member 2 may cover the plurality of light-emitting elements 1 such that all of the light-emitting elements 1 are embedded therein, or may cover the light-emitting elements 1 such that the electrodes of the light-emitting elements 1 are exposed as illustrated in FIG. 6E. In addition, after all of the plurality of light-emitting elements 1, that is, all of the plurality of light-emitting elements 1 including the electrodes, are covered with the material of the covering member 2 so as to be embedded therein, a part of the material of the covering member 2 may be removed so as to expose the electrodes of the light-emitting elements 1. Such removal can be performed by a method known in the art, such as etching or grinding.

### Singulation

Subsequently, as illustrated in FIG. 6F, the layered body is singulated in groups of a plurality of the first light-transmissive members 31, second light-transmissive members 32, and light-emitting elements 1 such that the thinned second light-transmissive members 32 are disposed on the outermost periphery. In other words, in the thinned second light-transmissive member 32 between the light-emitting elements 1, singulation is performed such that at least the entire light-transmissive sheet 3a in the thickness direction is cut. The singulation may be performed by laser dicing, blade dicing or the like. The singulation is preferably performed, for example, in a portion on the outer side of the outline (broken line Q) connecting the lateral surfaces Is on the outer side of the light-emitting elements 1g located on the outer side in FIG. 2. The light source 10 can be formed by the series of methods.

The manufacturing method of the light source 10 may further include the following steps.

### Formation of Grooves

As illustrated in FIG. 6G, after the covering member 2 is disposed, the groove 2A may be formed around the outer periphery of the plurality of light-emitting elements and the grooves 2B may be formed between the light-emitting elements 1 adjacent to each other, in the covering member 2.

Either of the groove 2A and the grooves 2B may be formed first. In addition, the groove 2A and the grooves 2B may be formed after forming the covering member 2 and before singulation. The groove 2A and the grooves 2B can be formed by laser dicing, blade dicing, or the like.

### Formation of Light-Blocking Member 2C

Furthermore, after forming the groove 2A and/or the grooves 2B, the light-blocking member 2C may be disposed in the groove 2A and the grooves 2B. The light-blocking member 2C may be disposed only in the groove 2A and the grooves 2B so as to expose the electrodes of the light-emitting elements 1, or as illustrated in FIG. 6H, the light-blocking member 2C may cover all of the plurality of light-emitting elements 1, that is, all of the light-emitting elements 1 including the electrodes, such that they are embedded, and then as illustrated in FIG. 6I, a part of the material of the light-blocking member 2C may be removed such that the electrodes of the light-emitting elements 1 are exposed. Such removal can be performed by a method known in the art, such as etching or grinding.

### Formation of Conductive Film 8

As illustrated in FIG. 6J, a conductive film 8a is formed on the covering member 2 and the electrodes exposed from the covering member 2. The conductive film 8a may be formed of any material having conductivity, and can be formed of a metal, such as copper, aluminum, gold, silver, platinum, titanium, tungsten, palladium, iron, or nickel, an alloy containing any of those metals, or the like. Subsequently, parts of the conductive film 8a covering the covering member 2 are removed by, for example, etching, laser ablation, or the like. Accordingly, as illustrated in FIG. 6K, the conductive films 8 including a part that covers the electrodes and another part that covers the covering member 2 can be formed. The thickness of the conductive film can be appropriately set according to the performance to be obtained, the material to be used, and the like. For example, when the conductive film is removed by laser ablation, the thickness of the conductive film is preferably 1 μm or less, and more preferably in a range from 10 nm to 100 nm.

### Light-Emitting Module

As illustrated in FIG. 7, a light-emitting module 20 of one embodiment includes a module substrate 21 and the light source 10 disposed on the module substrate 21. The substrate 21 includes a wiring layer on a surface thereof, and the wiring layer is formed such that, for example, the light-emitting elements can be matrix-driven in units of segments. The light source 10 may be disposed on the module substrate 21 with a sub-mount, such as the wiring substrate 50, interposed therebetween.

The light-emitting module 20 may include a lens 11 disposed on the light source 10. Here, as the lens 11, a lens exhibiting any of various functions, such as a convex lens, a concave lens, and a Fresnel lens, can be used. In addition, a housing 12 may be provided to support the lens 11.

Even in the light-emitting module including the lens 11, when the light source 10 is viewed through the lens 11, the white color of the outer periphery of the light source 10 is hard to be visually recognized, thus allowing the light-emitting module to have a good appearance through the lens.

The light source and the light-emitting module of the present disclosure can be used for a flashlight source of a camera, a headlight of a vehicle, a backlight of a liquid crystal display, various lighting fixtures, and the like.

What is claimed is:

1. A light source comprising:
a plurality of light-emitting elements;
a covering member disposed between adjacent ones of the plurality of light-emitting elements and on an outer periphery surrounding an entirety of the plurality of light-emitting elements with upper surfaces of the plurality of light-emitting elements being exposed from the covering member, the covering member collectively holding the plurality of light-emitting elements; and
a plurality of light-transmissive members including
a plurality of first light-transmissive members disposed on respective ones of the plurality of light-emitting elements, and
at least one second light-transmissive member disposed on the covering member located on the outer periphery, the at least one second light-transmissive member having a thickness smaller than a thickness of each of the plurality of first light-transmissive members.

2. The light source according to claim 1, wherein
the covering member is disposed between adjacent ones of the plurality of light-transmissive members with upper surfaces of the plurality of light-transmissive members being exposed from the covering member.

3. The light source according to a claim 1, wherein
the at least one second light-transmissive member includes a protrusion and a recess on a surface on a side of the covering member.

4. The light source according to claim 1, wherein
the at least one second light-transmissive member includes an inclined portion on a surface on a side of the covering member.

5. The light source according to claim 1, further comprising
a third light-transmissive member covering upper surfaces of the plurality of light-transmissive members.

6. The light source according to claim 1, further comprising
a plurality of third light-transmissive members covering upper surfaces of the respective ones of the plurality of light-transmissive members.

7. The light source according to claim 1, wherein
the covering member constitutes a part of a lower surface of the light source, the lower surface defining a groove on the outer periphery surrounding the entirety of the plurality of light-emitting elements.

8. The light source according to claim 1, wherein
the covering member constitutes a part of a lower surface of the light source, the lower surface defining a groove between adjacent ones of the plurality of light-emitting elements.

9. The light source according to claim 7, further comprising
a light-blocking member disposed in the groove.

10. The light source according to claim 1, wherein
the plurality of first light-transmissive members are disposed such that an outer periphery of an entirety of the plurality of first light-transmissive members has a rectangular shape in a plan view, and
the plurality of light-transmissive members further include a plurality of additional second light-transmissive members, and the at least one second light-transmissive member and the additional second light-transmissive members are disposed along the outer periphery having the rectangular shape.

11. The light source according to claim 10, wherein
each of the at least one second light-transmissive member and the additional second light-transmissive members has a lateral surface exposed from the covering member and constituting a part of an outer lateral surface of the light source.

12. The light source according to claim 1, wherein
a distance between adjacent ones of the first light-transmissive members is smaller than a distance between adjacent ones of the light-emitting elements.

13. The light source according to claim 1, wherein
the plurality of light-transmissive members contain a phosphor.

14. The light source according to claim 1, wherein
the plurality of light-emitting elements have an emission peak wavelength in a range from 400 nm to 490 nm, and
the plurality of light-transmissive members contain a phosphor having an emission peak wavelength in a range from 520 nm to 680 nm.

15. The light source according to claim 1, wherein
the at least one second light-transmissive member is disposed adjacent to one of the first light-transmissive members in a plan view, and a width of the at least one second light-transmissive member is in a range from 5% to 100% of a width of the one of the first light-transmissive members adjacent to the at least one second light-transmissive member in an arrangement direction of the at least one second light-transmissive member and the one of the first light-transmissive members.

16. A light-emitting module comprising:
the light source according to claim 1; and
a module substrate on which the light source is mounted.

17. The light-emitting module according to claim 16, further comprising a lens disposed on the light source.
